(19) United States
(12) Patent Application Publication
(10) Pub. No.: US 2025/0311219 A1
(43) Pub. Date: Oct. 2, 2025

(54) METHODS OF FORMING MICROELECTRONIC DEVICES INCLUDING BLOCK AND SUB-BLOCK STRUCTURES, AND RELATED ELECTRONIC DEVICES

(71) Applicant: Micron Technology, Inc., Boise, ID (US)

(72) Inventors: Jiewei Chen, Meridian, ID (US); Fatma Arzum Simsek-Ege, Boise, ID (US); Maryam Sayyah, Boise, ID (US)

(21) Appl. No.: 19/067,568

(22) Filed: Feb. 28, 2025

Related U.S. Application Data
(60) Provisional application No. 63/571,997, filed on Mar. 29, 2024.

(51) Int. Cl. H10B 43/27

(52) U.S. Cl. CPC H10B 43/27

(57) ABSTRACT

An electronic device comprises a stacked structure divided into blocks and composed of a first stack structure, a second stack structure overlying the first stack structure, and a third stack structure overlying the second stack structure. Each of the first, second and third stack structures comprises tiers of vertically alternating conductive structures and insulative structures. The electronic device comprises a memory pillar extending vertically through the first and second stack structures, a channel pillar extending vertically through the third stack structure, an inter-block pillar structure interposed horizontally between the blocks, and an isolated dielectric structure segmenting the blocks into sub-blocks. The isolated dielectric structure comprises a first portion and a second portion over the first portion. The first portion of the isolated dielectric structure overlies the third stack structure. The second portion extends vertically through at least a portion of the third stack structure. Related methods are also described.

### CROSS-REFERENCE TO RELATED APPLICATIONS

This application claims the benefit under 35 U.S.C. § 119(e) of U.S. Provisional Patent Application Ser. No. 63/571,997, filed Mar. 29, 2024, the disclosure of which is hereby incorporated herein in its entirety by this reference.

### TECHNICAL FIELD

Embodiments disclosed herein relate to the field of electronic device design and fabrication. More particularly, embodiments of the disclosure relate to methods of forming microelectronic devices including blocks and sub-block structures, and to related electronic devices and systems.

### BACKGROUND

A continuing goal of the electronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more stack structures including tiers of conductive structures and insulative structures. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive structures of the tiers of the stack structure(s) of the memory device and access lines (e.g., word lines) so that the memory cells of the vertical memory array can be uniquely selected for writing, reading, or erasing operations.

As vertical memory array technology has advanced, additional memory density has been provided by forming vertical memory arrays to include stacks comprising additional tiers of conductive structures. The stacks may be segmented into blocks and sub blocks. As the number of tiers of the conductive structures increases, processing conditions of the formation of aligned contacts to various components in different blocks and sub blocks of an electronic device become increasingly difficult. Furthermore, as the height of the stacks increases to facilitate additional memory cells in the vertical memory arrays, the blocks may be prone to bending during various processing acts. For example, during replacement gate processing acts, the blocks may be prone to bending during or after removal of portions of the tiers to be replaced with the conductive structures. Bending of the blocks may cause mis-alignment of contacts in various components of the electronic device, thus reducing reliability of the vertical memory strings.

### BRIEF DESCRIPTION OF THE DRAWINGS

FIGS. 1 and 2 are simplified partial cross-sectional views illustrating a conventional method of forming an electronic device;

FIG. 3 is a simplified partial top-down view of an electronic device of FIG. 2;

FIGS. 4 through 12 are simplified partial cross-sectional views illustrating a method of forming an electronic device, in accordance with embodiments of the disclosure;

FIG. 13 is a simplified partial top-down view of an electronic device of FIG. 12, in accordance with embodiments of the disclosure;

FIG. 14 is a partial cutaway perspective view of an electronic device, in accordance with embodiments of the disclosure;

FIG. 15 is a block diagram of an electronic system, in accordance with embodiments of the disclosure; and

FIG. 16 is a block diagram of a processor-based system, in accordance with embodiments of the disclosure.

### DETAILED DESCRIPTION

An electronic device (e.g., a microelectronic device) that includes a stacked structure divided into blocks, an inter-block pillar structure horizontally interposed between the blocks of the stacked structure, and an isolated dielectric structure segmenting the blocks into sub blocks is disclosed. The stacked structure of the electronic device comprises a first stack structure adjacent to a source structure, a second stack structure overlying the first stack structure, and a third stack structure (e.g., a select gate drain stack structure) overlying the second stack structure. Each of the stack structures comprises tiers of vertically alternating conductive structures and insulative structures. The inter-block pillar structure extends vertically through the stacked structure (i.e., the first stack structure, the second stack structure, and the third stack structure). A memory pillar comprising strings of memory cells extends vertically through the first and second stack structures. A channel pillar comprising a channel material extends vertically through the third stack structure and adjacent to the memory pillar. The isolated dielectric structure is positioned laterally (e.g., horizontally) between the neighboring channel pillars and extends vertically through at least a portion of the third stack structure. The isolated dielectric structure comprises a first portion and a second portion over the first portion, with the first portion being relatively wider than the second portion. The first portion of the isolated dielectric structure is interposed horizontally between two adjacent dielectric materials overlying the third stack structure, while the second portion of the isolated dielectric structure extends vertically through at least a portion of the third stack structure. The electronic device further comprises a conductive contact interposed vertically between the second pillar structure and the third pillar structure, with the conductive contact electrically coupling (e.g., electrical communicating) the first and second pillar structures and the third pillar structure.

In a conventional method of forming an electronic device, for example, the sacrificial isolation structure (which is fabricated into an isolated dielectric structure in the subsequent processing acts) is formed after a replacement gate process, while the channel pillar (e.g., the third pillar structure extending vertically through the third stack structure) is formed before the replacement gate process. Due to block bending, there may be mis-alignment between the isolated dielectric structure (formed after the replacement gate process) and the channel pillar (formed before the replacement gate process).

In a method of forming an electronic device in accordance with embodiments of the disclosure, the sacrificial isolation structure may be formed prior to conducting the replacement gate process. Since both the sacrificial isolation structure and the channel pillar are formed prior to the gate replacement process, the mis-alignment between the isolated dielectric structure and the channel pillar may be reduced or minimized.

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional electronic device fabrication techniques employed in the industry. In addition, the description provided below does not form a complete process flow for manufacturing an electronic device (e.g., a memory device, such as 3D NAND Flash memory device). The structures described below do not form a complete electronic device. Only those process acts and structures necessary to understand the embodiments of the disclosure are described in detail below. Additional acts to form a complete electronic device from the structures may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Stated another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, the term “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “conductive material” means and includes an electrically conductive material. The conductive material may include one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, a “conductive structure” means and includes a structure formed of and including one or more conductive materials.

As used herein, a “insulative material” or a “dielectric material” means and includes an electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓNy)), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, an “insulative structure” means and includes a structure formed of and including an insulative material.

As used herein, a “dielectric structure” means and includes a structure formed of and including one or more dielectric materials.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “critical dimension” means and includes a dimension of a feature within design tolerances in order to achieve the desired performance of the device and to maintain the performance consistency of the device. This dimension may be obtained on a device structure as a result of different combinations of fabrication processes, which may include, but are not limited to, photolithography, etch (dry/wet), diffusion, or deposition acts.

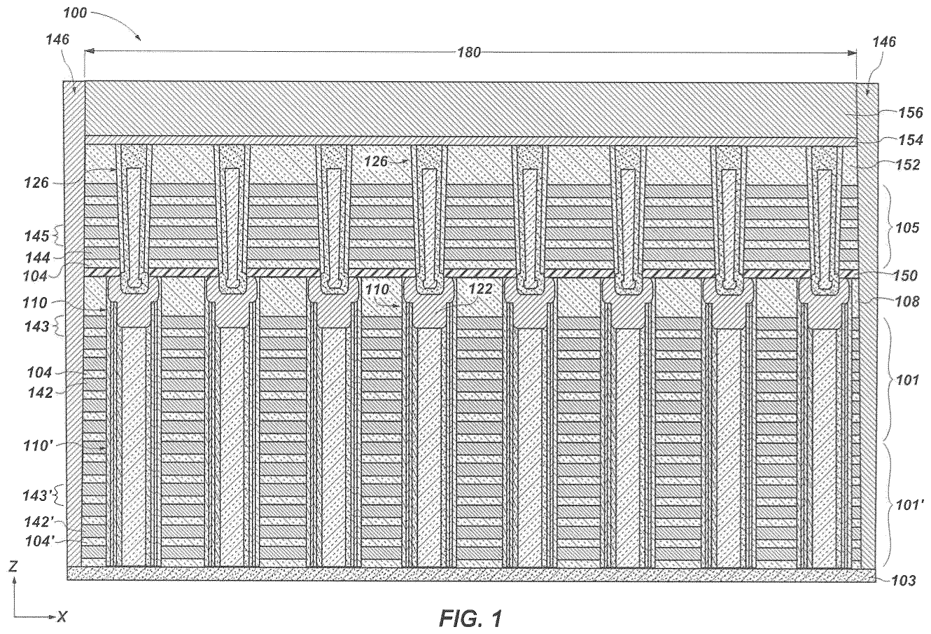

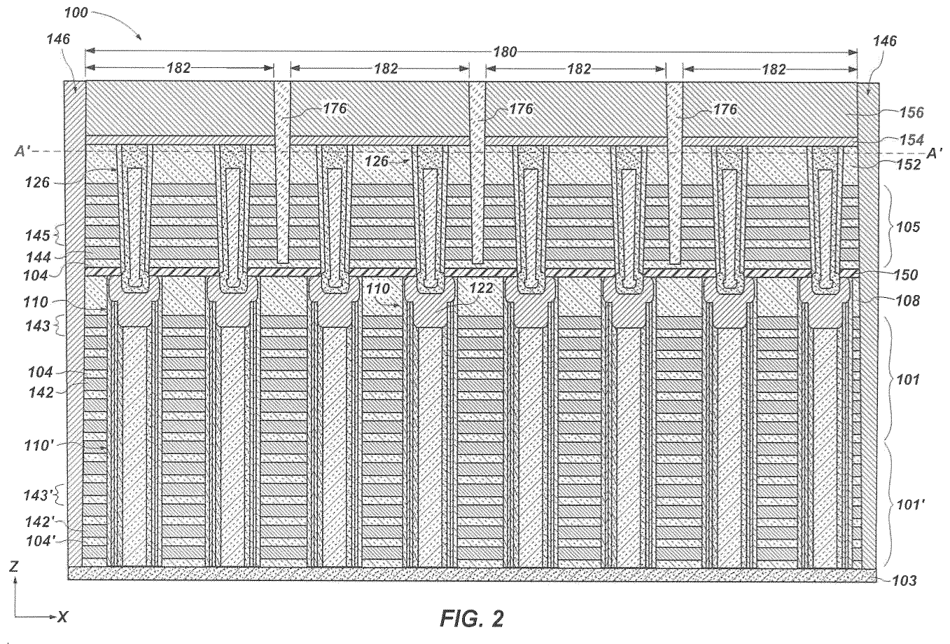

For comparison purpose, FIGS. 1 and 2 illustrate a conventional method of forming a microelectronic device. For convenience in describing these figures, a first horizontal direction may be defined as the X-direction and a second horizontal direction, which is transverse (e.g., perpendicular) to the first horizontal direction, as the Y-direction. A third direction, which is transverse (e.g., perpendicular) to each of the first horizontal direction and the second horizontal direction, may be defined as the Z-direction (i.e., vertical direction).

FIG. 1 illustrates an electronic device 100 after conducting a replacement gate process. The electronic device 100 comprises a first stack structure 101′ overlying a source 103, a first pillar structure 110′ extending vertically through the first stack structure 101′, a second stack structure 101 overlying the first stack structure 101′, a second pillar structure 110 extending vertically through the second stack structure 101, a third stack structure 105 overlying the second stack structure 101, a third pillar structure 126 extending vertically through the third stack structure 105, and a dielectric material 108 between the second stack structure 101 and the third stack structure 105. The electronic device 100 also includes a conductive contact 122 interposed vertically between the second pillar structure 110 and the third pillar structure 126, with the conductive contact 122 electrically coupling (e.g., electrical communicating) the first and second pillar structures 110′, 110 and the third pillar structure 126. Furthermore, the electronic device 100 includes an upper insulative material 152 over the third stack structure 105, a barrier material 154 over the upper insulative material 152, and an uppermost insulative material 156 overlying the barrier material 154. The electronic device 100 includes an inter-block pillar structure 146 extending vertically through the first stack structures 101′, the second stack structures 101, and the third stack structures 105 and segmenting the electronic device 100 into blocks 180. Each of the first and second stack structures 101′, 101 of the electronic device 100 comprises tiers 143′, 143 of vertically alternating conductive structures 142′, 142 and insulative structures 104′, 104. The third stack structures 105 of the electronic device 100 comprises tiers 145 of vertically alternating conductive structures 144 and insulative structures 104. The electronic device 100 at the process stage shown in FIG. 1 may be formed by conventional techniques.

A number of tiers 143′, 143 of the first and second stack structure 101′, 101 may be in a range of from about 32 to about 256. However, as efforts to increase the memory density of an electronic device continue, an increase in the numbers of tiers 143′, 143 in the first and second stack structure 101′, 101 may occur. The inter-block pillar structure 146 extends vertically through the first stack structures 101′, the second stack structures 101, and the third stack structures 105; therefore, the aspect ratio of the inter-block pillar structure 146 also continues to increase. Due to the high aspect ratio of the inter-block pillar structure 146, the blocks 180 are prone to bending during or after a replacement gate process.

Referring to FIG. 2, openings are formed extending vertically at least partially through portions of the insulative structures 104 and the conductive structures 144 of the tiers 145 of the third stack structure 105. Upon filling the openings with a dielectric material, the isolated dielectric structures 176, 176′ are formed that segment the blocks 180 of the electronic device 100 into sub-blocks 182. Block bending may cause mis-alignment of various components (e.g., the third pillar structures 126, the isolated dielectric structures 176, 176′) of the electronic device 100, and therefore jeopardize the performance and/or reduce the reliability of the electronic device. For example, there may be mis-alignment between the isolated dielectric structure 176′ and the horizontally neighboring third pillar structures 126, leading to additional mis-alignments and increasingly difficulty in forming various components of the electronic device 100 in subsequent processing acts.

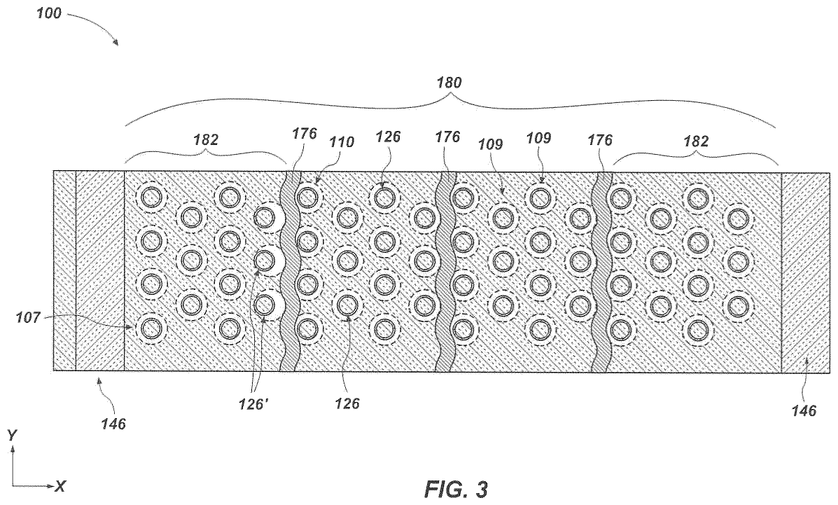

FIG. 3 is a partial top-down view along line A-A′ of the electronic device 100 of FIG. 2. The electronic device 100 may be divided into blocks 180 between horizontally neighboring inter-block pillar structures 146 (e.g., in the X-direction). Each block 180 may be divided into sub-blocks 182 between horizontally neighboring isolated dielectric structures 176, 176′ (e.g., in the X-direction). Each sub-block 182 includes rows 107 of the second pillar structures 110 and the third pillar structures 126 extending in a first horizontal (e.g., lateral) direction (e.g., in the X-direction) and columns 109 extending in a second horizontal direction (e.g., in the Y-direction).

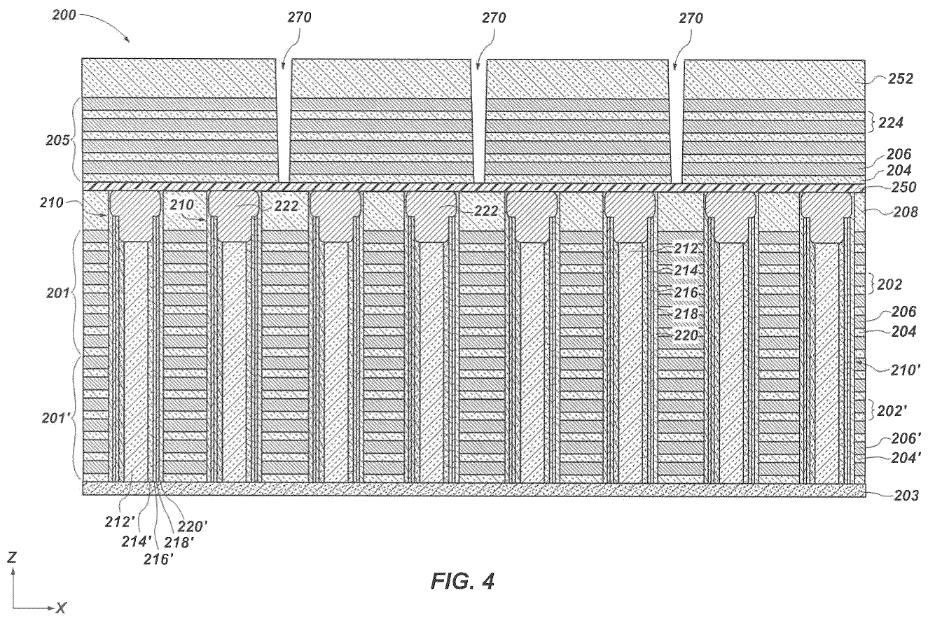

FIGS. 4 through 12 illustrate a method of forming a microelectronic device, in accordance with embodiments of the disclosure.

As shown in FIG. 4, an electronic device 200 may be formed to include a first stack structure 201′ overlying a source 203 (e.g., a source tier, a source plate), a second stack structure 201 overlying the first stack structure 201′, a third stack structure 205 overlying the second stack structure 201, a first pillar structure 210′ extending vertically through the first stack structure 201′, a second pillar structure 210 extending vertically through the second stack structure 201, a dielectric material 208 between the second stack structure 201 and the third stack structure 205, and an upper insulative material 252 over the third stack structure 205. The electronic device 200 may optionally include an etch stop material 250 between the dielectric material 208 and the third stack structure 205.

The first stack structure 201′ includes a vertically alternating sequence of insulative structures 204′ and sacrificial insulative structures 206′ arranged in tiers 202′. Each of the tiers 202′ may individually include an insulative structure 204′ directly vertically neighboring (e.g., adjacent) the sacrificial insulative structure 206′. In some embodiments, a number (e.g., quantity) of tiers 202′ of the first stack structure 201′ may be in a range of from about 32 to about 256 of the tiers 202′. In some embodiments, the first stack structure 201′ includes 128 of the tiers 202′. However, the disclosure is not so limited, and the first stack structure 201′ may include a different number of the tiers 202′.

The second stack structure 201 includes a vertically alternating sequence of insulative structures 204 and sacrificial insulative structures 206 arranged in tiers 202. Each of the tiers 202 may individually include an insulative structure 204 directly vertically neighboring (e.g., adjacent) the sacrificial insulative structure 206. In some embodiments, a number (e.g., quantity) of tiers 202 of the second stack structure 201 may be in a range of from about 32 to about 256 of the tiers 202. In some embodiments, the second stack structure 201 includes 128 of the tiers 202. However, the disclosure is not so limited, and the second stack structure 201 may include a different number of the tiers 202.

While FIG. 4 shows the materials of the first and second pillar structures 210′, 210 as extending through the first and second stack structures 201′, 201 and exhibiting substantially the same dimensions in the X-direction, the dimensions in the X-direction of the materials may be different such that the first and second stack structures 201′, 201 exhibit tapered cross-sectional shapes. In other words, the materials of the first and second pillar structures 210′, 210 may be uniform in dimension along a height of the first and second pillar structures 210′, 210 as shown in FIG. 4. However, the materials of the first and second pillar structures 210′, 210 may vary in dimension, as long as a portion of the second pillar structures 210 contacts (e.g., directly contacts) a portion of the first pillar structures 210′ to provide the electrical communication.

Although FIG. 4 has been described and illustrated as including first stack structure 101′ directly over the source 103, the disclosure is not so limited. In other embodiments, the first stack structure 101′ overlies another stack structure comprising additional tiers of the insulative structures and the sacrificial insulative structures.

The source 203 may be formed of and include, for example, a semiconductor material doped with one or more p-type conductivity materials (e.g., polysilicon doped with at least one p-type dopant, such as one or more of boron, aluminum, and gallium) or one or more n-type conductivity materials (e.g., polysilicon doped with at least one n-type dopant, such as one or more of arsenic, phosphorous, antimony, and bismuth).

The dielectric material 208 may be located over an uppermost one of the tiers 202. The dielectric material 208 may be formed of and include an electrically insulative material, such as, for example, one or more of phosphosilicate glass (PSG), borosilicate glass (BSG), fluorosilicate glass (FSG), borophosphosilicate glass (BPSG), and silicon dioxide. In some embodiments, the dielectric material 208 comprises the same material composition as the insulative structures 204. In some embodiments, the dielectric material 208 comprises silicon dioxide.

The electronic device 200 may include a first pillar structure 210′ of materials vertically extending (e.g., in the Z-direction) through the first stack structure 201′, and a second pillar structure 210 of materials vertically extending through the dielectric material 208 and the second stack structure 201. The first and second pillar structure 210′, 210 may each individually comprise an insulative material 212′, 212; a channel material 214′, 214 horizontally neighboring the insulative material 212′, 212; a tunnel dielectric material 216′, 216 horizontally neighboring the channel material 214′, 214; a memory material 218′, 218 horizontally neighboring the tunnel dielectric material 216′, 216; and a dielectric charge blocking material 220′, 220 horizontally neighboring the memory material 218′, 218. The dielectric charge blocking material 220′ may be horizontally neighboring one of the sacrificial insulative structures 206′ of one of the tiers 202′ of the first stack structure 201′. The dielectric charge blocking material 220 may be horizontally neighboring one of the sacrificial insulative structures 206 of one of the tiers 202 of the second stack structure 201. As will be described herein, during fabrication of electronic device 200, the materials of the first and second pillar structures 210′, 210 may form memory cells (e.g., strings of memory cells).

The insulative materials 212′, 212 may be formed of and include an electrically insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material (e.g., silicon nitride), an oxynitride (e.g., silicon oxynitride), a dielectric carbon nitride material (e.g., silicon carbon nitride), a dielectric carboxynitride material (e.g., silicon carboxynitride), or combinations thereof. In some embodiments, the insulative materials 212′, 212 comprises silicon dioxide.

The channel materials 214′, 214 may be formed of and include one or more of a semiconductor material and an oxide semiconductor material. Non-limiting examples of the semiconductor material include an elemental semiconductor material (e.g., polycrystalline silicon); a III-V compound semiconductor; a II-VI compound semiconductor material; an organic semiconductor material; GaAs; InP; GaP; GaN, or any other semiconductor materials. In some embodiments, the channel materials 214′, 214 include amorphous silicon or polysilicon. In some embodiments, the channel materials 214′, 214 comprises a doped semiconductor material.

The tunnel dielectric materials 216′, 216 may be formed of and include a dielectric material through which charge tunneling can be performed under suitable electrical bias conditions, such as through hot-carrier injection or by Fowler-Nordheim tunneling induced charge transfer. By way of non-limiting example, the tunnel dielectric materials 216′, 216 may be formed of and include one or more of silicon oxide, silicon nitride, silicon oxynitride, dielectric metal oxides (such as aluminum oxide and hafnium oxide), dielectric metal oxynitride, dielectric metal silicates, alloys thereof, or combinations thereof. In some embodiments, the tunnel dielectric materials 216′, 216 comprises silicon dioxide. In other embodiments, the tunnel dielectric materials 216′, 216 comprises silicon oxynitride.

The memory materials 218′, 218 may comprise a charge trapping material or a conductive material. The memory materials 218′, 218 may be formed of and include one or more of silicon nitride, silicon oxynitride, polysilicon (doped polysilicon), a conductive material (e.g., tungsten, molybdenum, tantalum, titanium, platinum, ruthenium, alloys thereof, or a metal silicide such as tungsten silicide, molybdenum silicide, tantalum silicide, titanium silicide, nickel silicide, cobalt silicide, or a combination thereof), a semiconductive material polycrystalline or amorphous semiconductor material including at least one elemental semiconductor element or at least one compound semiconductor material, conductive nanoparticles (e.g., ruthenium nanoparticles), metal dots. In some embodiments, the memory materials 218′, 218 comprises silicon nitride.

The dielectric charge blocking materials 220′, 220 may be formed of and include a dielectric material such as, for example, one or more of an oxide (e.g., silicon dioxide), a nitride (silicon nitride), and an oxynitride (silicon oxynitride), or other materials. In some embodiments, the dielectric charge blocking materials 220′, 220 comprises silicon oxynitride.

In some embodiments, the tunnel dielectric materials 216′, 216, the memory materials 218′, 218 and the dielectric charge blocking materials 220′, 220 together may comprise a structure configured to trap a charge, such as, for example, an oxide-nitride-oxide (ONO) structure. In some such embodiments, the tunnel dielectric materials 216′, 216 comprises silicon dioxide, the memory materials 218′, 218 comprises silicon nitride, and the dielectric charge blocking materials 220′, 220 comprises silicon dioxide.

With continued reference to FIG. 4, upper portions of the second pillar structures 210 may be removed to recess the second pillar structures 210 relative to an uppermost surface of the dielectric material 208. In some embodiments, a portion of the insulative material 212 and the channel material 214 may be recessed vertically lower (e.g., in the Z-direction) than the other components of the second pillar structures 210 (e.g., the tunnel dielectric material 216, the memory material 218, the dielectric charge blocking material 220). In some embodiments, a conductive material may be formed within the recesses to form a conductive contact 222. The conductive contact 222 may be formed of and include a polysilicon or another material formulated to exhibit an etch selectivity with respect to the material of the dielectric material 208 and, in some embodiments, with respect to one or more of the materials of the second pillar structures 210. In some embodiments, the conductive contact 222 is electrically connected to (e.g., in electrical communication with) the channel material 214. In some embodiments, the conductive contact 222 comprises doped polysilicon. In some embodiments, the conductive contact 222 is doped with one or more n-type dopants such as, for example, phosphorus. In some embodiments, the conductive contact 222 is lightly doped (e.g., at a concentration of about 1×10¹⁸ atoms/cm³). While FIG. 4 shows the conductive contact 222 having a bulbous shape at the bottom portion, the disclosure is not limited and any shape of the conductive contact 222 may be formed. As non-limiting examples, the conductive contact 222 may comprise sharp corners or, alternatively, the conductive contact 222 may comprise rounded corners.

After the formation of the conductive contact 222, a third stack structure 205 (e.g., a select gate drain stack structure) may be formed over the second stack structure 201. The third stack structure 205 may include a vertically alternating sequence of additional insulative structures 204″ and additional sacrificial insulative structures 206″ formed over an optional etch stop material 250. The additional insulative structures 204″ and the additional sacrificial structures 206″ may be arranged in tiers 224″. Although FIG. 4 shows that the third stack structure 205 includes four tiers 224″, the disclosure is not so limited and the third stack structure 205 may include a different number of the tiers 224″.

The insulative structures 204′, 204, 204″ may be formed of and include, for example, at least one dielectric material, such as one or more of an oxide material (e.g., silicon dioxide), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃). In some embodiments, the insulative structures 204′, 204, 204″ are formed of and include silicon dioxide.

The sacrificial insulative structures 206′, 206, 206″ may be formed of and include an insulative material that is different than, and exhibits an etch selectivity with respect to, the insulative structures 204′, 204, 204″. In some embodiments, the sacrificial insulative structures 206′, 206, 206″ are formed of and include a nitride material (e.g., silicon nitride) or an oxynitride material (e.g., silicon oxynitride). In some embodiments, the sacrificial insulative structures 206′, 206, 206″ comprise silicon nitride. As will be described herein, during fabrication of electronic device 200, one or more portions of the sacrificial insulative structures 206 may be replaced to form conductive structures, such as select gate structures, which may comprise one or more select gate drain (SGD) structures, and an additional select gate structure, which may comprise a select gate source (SGS) structure.

The etch stop material 250, if present, may be formed of and include, for example, a material exhibiting an etch selectivity with respect to the insulative structures 204 and the sacrificial insulative structures 206. In some embodiments, the etch stop material 250 comprises a carbon-containing material (e.g., silicon carbon nitride). In some such embodiments, the etch stop material 250 may facilitate an improved electric field through a channel region proximate the etch stop material 250 during use and operation of the electronic device 200. In some embodiments, the electronic device 200 may not include the etch stop material 250 between the second stack structure 201 and the third stack structure 205. In some such embodiments, the dielectric material 208 (e.g., alone) may intervene between the second stack structure 201 and the third stack structure 205.

The upper insulative material 252 may be formed over the third stack structure 205 and comprise the same material composition as the dielectric material 208. In some embodiments, the upper insulative material 252 comprises silicon dioxide. Furthermore, the upper insulative material 252 may have a greater thickness in a vertical direction (e.g., in the Z-direction) than the neighboring insulative structures 204″ of the third stack structure 205.

With continued reference to FIG. 4, openings 270 may be formed extending vertically through the upper insulative material 252 and portions of the tiers 224″ of the third stack structure 205. For example, the openings 270 may be formed by removing portions of the upper insulative material 252, as well as portions of the insulative structures 204″ and the sacrificial structure 206″ of the third stack structure 205. In some embodiments, the openings 270 of the third stack structure 205 may be substantially centered in the horizontal direction (e.g., X-direction, Y-direction, and/or X- and Y-directions) between the underlying neighboring second pillar structures 210 of the second stack structure 201. The portions of the upper insulative material 252, as well as the portions of the insulative structures 204″ and the sacrificial insulative structures 206″ in the tiers 224″ may, for example, be removed by one or more material removal processes (e.g., a single etch process). The openings 270 may be formed (e.g., patterned) using substantially linear (e.g., substantially straight) openings in a resist material (e.g., a photoresist material, a mask material) (not shown) in the Y-direction. In some embodiments, the openings 270 may extend through the upper insulative material 252 and the tiers 224″ of the third stack structure 205, and terminate at the upper surface of the etch stop material 250 (if present). In some embodiments, the openings 270 terminate within a lowermost one of the tiers 224″ of the third stack structure 205.

The openings 270 may have any suitable transverse cross-sectional shape such as, for example, a substantially circular cross-sectional shape, a substantially square cross-sectional shape, a substantially elliptical cross-sectional shape, or a substantially triangular cross-sectional shape. In some embodiments, each of the openings 270 may individually exhibit a substantially circular cross-sectional shape having a substantially circular cross-sectional area. While three openings 270 are shown in FIG. 4 for clarity, the disclosure is not limited and any number of openings 270 may be formed.

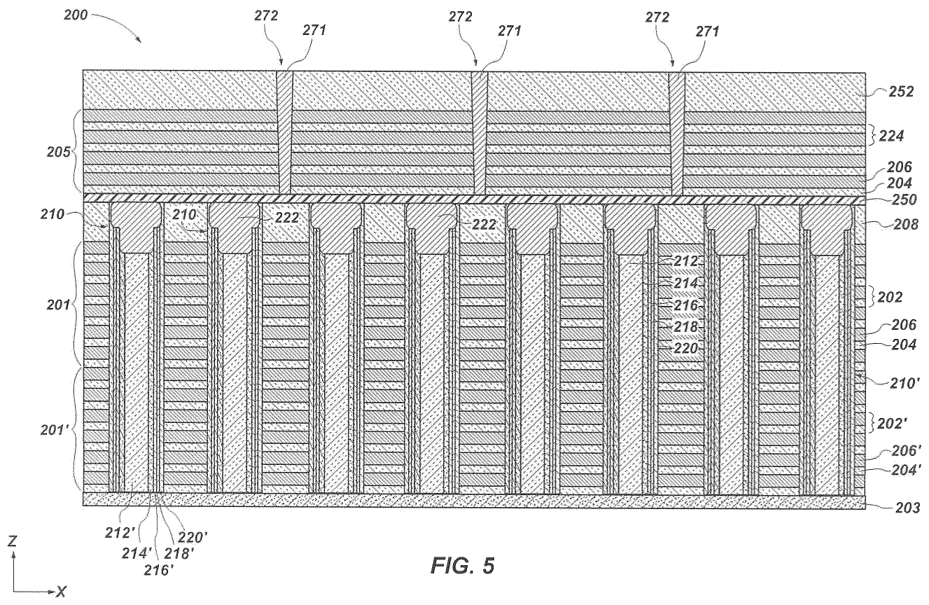

Referring to FIG. 5, the openings 270 may be filled with a sacrificial dielectric material 271 to produce sacrificial isolation structures 272. The sacrificial dielectric material 271 may be formed of and include, for example, an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride), an oxynitride material (e.g., silicon oxynitride), a dielectric carbon nitride material (e.g., silicon carbon nitride), a dielectric carboxynitride material (e.g., silicon carboxynitride), or combinations thereof. In some embodiments, the sacrificial dielectric material 271 comprises a nitride material (e.g., silicon nitride), although other materials may be contemplated, so long as the sacrificial dielectric material 271 exhibits etch selectivity relative to surrounding materials, e.g., in the subsequent processing acts as discussed below.

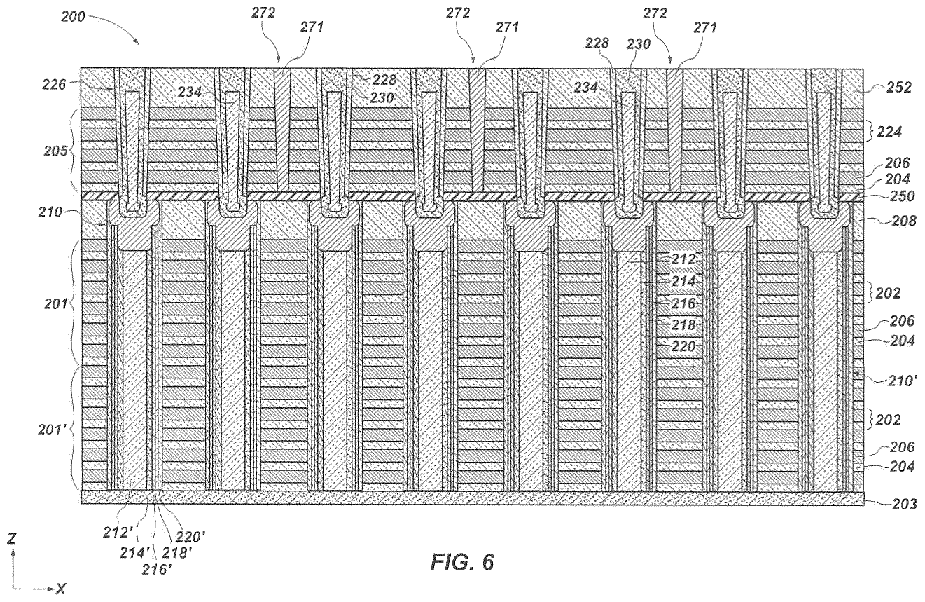

Referring to FIG. 6, third pillar structure 226 (e.g., a select gate drain stack structure) may be formed vertically extending (e.g., in the Z-direction) through the upper insulative material 252 and the third stack structure 205. At least some (e.g., each) of the third pillar structures 226 are substantially horizontally aligned (e.g., are concentric) with the second pillar structures 210. For example, a central axis of each of the third pillar structures 226 may be substantially horizontally aligned (e.g., in each of the X-direction and the Y-direction) relative to a central axis of the vertically underlying second pillar structures 210. The third pillar structures 226 may extend into the conductive contact 222, and horizontal boundaries (e.g., lateral edges) of the third pillar structures 226 may not extend beyond horizontal boundaries (e.g., lateral edges) of the underlying second pillar structures 210.

The third pillar structures (“channel pillars”) 226 may each individually include a liner material 228, a channel material 230 horizontally neighboring the liner material 228, and an insulative material 234 horizontally neighboring the channel material 230. The liner material 228 may be horizontally neighboring the additional sacrificial insulative structures 206″ of the tiers 224″ of the third stack structure 205. The channel material 230 may be horizontally interposed between the liner material 228 and the insulative material 234. The insulative material 234 may also vertically overlie (e.g., in the Z-direction) the channel material 230, such as a horizontally extending portion of the channel material 230 over the conductive contact 222.

The liner material 228 may be formed of and include, for example, an insulative material, such as one or more of the materials described above with reference to the insulative material 212. In some embodiments, the liner material 228 comprises silicon dioxide.

The channel material 230 of the third pillar structures 226 may be in electrical communication with the channel material 214 of the second pillar structures 210 and the channel material 214′ of the first pillar structures 210′ through the conductive contact 222. The channel material 230 may comprise one or more of the materials described above with reference to the channel materials 214′, 214. In some embodiments, the channel material 230 comprises the same material composition as the channel materials 214′, 214. In some embodiments, the channel material 230 may be continuous with the channel materials 214′, 214. Since the channel material 230 may comprise the same material composition as the channel materials 214′, 214, the channel material 230 is in electrical communication with the channel materials 214′, 214 through the conductive contact 222. The channel material 214′ of the first pillar structures 210′, the channel material 214 of the second pillar structures 210, the conductive contact 222, and the channel material 230 of the third pillar structure 226 may be collectively referred to as a channel region of the electronic device 200. The channel material 230 may comprise sharp corners or, alternatively, the channel material 230 may comprise rounded corners.

The insulative material 234 may be formed of and include one or more of the materials described above with reference to the insulative materials 212′, 212. In some embodiments, the insulative material 234 comprises substantially the same material composition as the insulative materials 212′, 212. In some embodiments, the insulative material 234 comprises silicon dioxide.

FIGS. 4 to 6 illustrate embodiments of the disclosure wherein the sacrificial isolation structures 272 are formed before the third pillar structures 226. However, the disclosure is not limited, and the third pillar structures 226 may be formed before the sacrificial isolation structures 272.

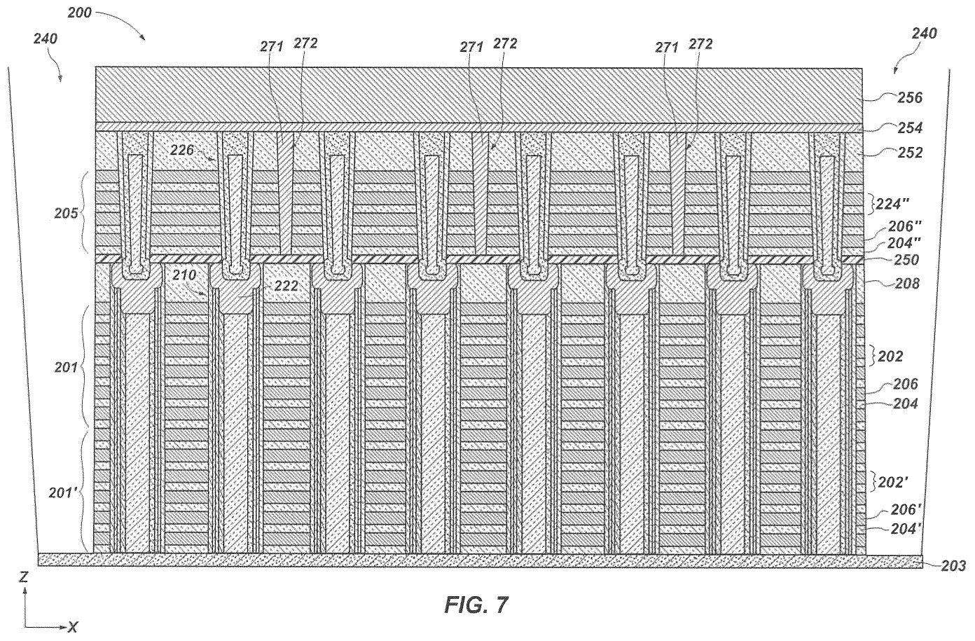

Referring to FIG. 7, a barrier material 254 (e.g., an etch stop material) may be formed over the upper insulative material 252, and an uppermost insulative material 256 may be formed adjacent to (e.g., on or over) the barrier material 254. In some embodiments, the barrier material 254 comprises substantially the same material composition as the etch stop material 250. In other embodiments, the barrier material 254 comprises a nitride material (e.g., silicon nitride, silicon oxynitride material, silicon oxycarbonitride material), although other materials may be contemplated, so long as the barrier material 254 exhibits etch selectivity relative to surrounding materials. In some embodiments, the barrier material 254 may be formed of and include silicon oxycarbonitride (SiOCN).

While FIG. 7 illustrates the uppermost insulative material 256 as a single material for convenience, multiple materials may be present. For example, the uppermost insulative material 256 may be formed to include a first uppermost insulative material adjacent to (e.g., on or over) the barrier material 254, and a second uppermost insulative material adjacent to (e.g., on or over) the first uppermost insulative material, collectively referred to herein as the uppermost insulative material 256.

The uppermost insulative material 256 may be formed of and include at least one dielectric material. In some embodiments, the uppermost insulative material 256 is formed of and includes silicon dioxide (SiO₂). A material composition of the uppermost insulative material 256 may be substantially the same as or different than a material composition of the insulative structures 204′ of the first stack structure 201′, the insulative structures 204 of the second stack structure 201, and the insulative structures 204″ of the third stack structure 205. The uppermost insulative material 256 and the upper insulative material 252 are separated from one another by the barrier material 254.

With continued reference to FIG. 7, replacement gate slots 240 may be formed extending vertically through the first stack structure 201′, the second stack structure 201, and the third stack structure 205. The replacement gate slots 240 may be referred to herein as so-called “replacement gate” slots. The replacement gate slots 240 may be formed by, for example, exposing the electronic device 200 to one or more etchants through a mask (not shown) to remove portions of the materials of the uppermost insulative material 256, the barrier material 254, the upper insulative material 252, the third stack structure 205, the etch stop material 250 (if any), the dielectric material 208, the second stack structure 201, and the first stack structure 201′, for example, by one or more etch processes. In some embodiments, the replacement gate slots 240 expose at least a portion of the source 203.

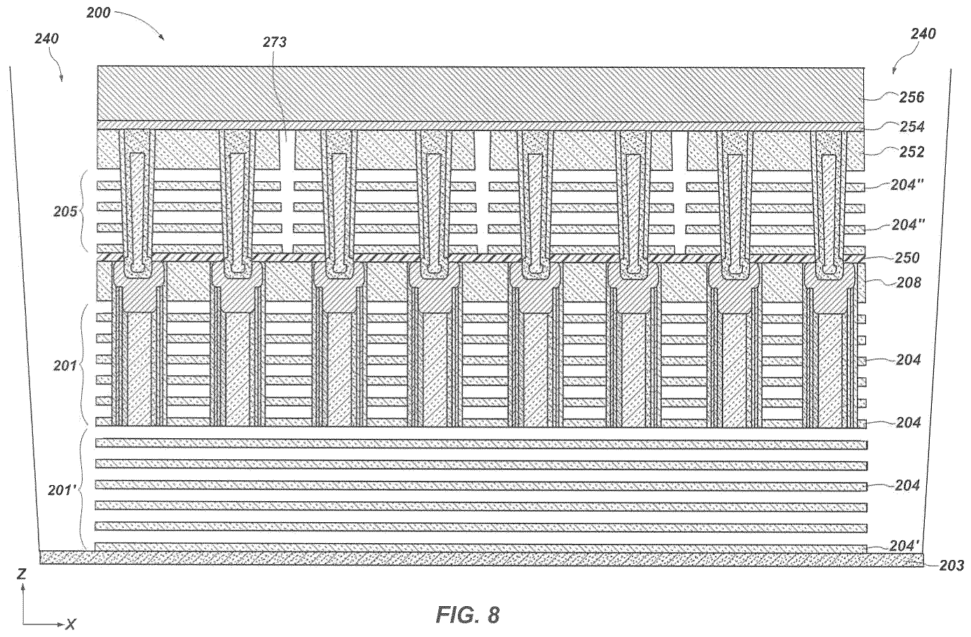

Referring to FIG. 8, the sacrificial insulative structures 206′ (FIG. 7) of the first stack structure 201′, the sacrificial insulative structures 206 of the second stack structure 201, and the sacrificial insulative structures 206″ of the third stack structure 205 may be at least partially (e.g., substantially) removed through the replacement gate slots 240 through the replacement gate process. By way of non-limiting example, the sacrificial insulative structures 206′, 206, 206″ may be at least partially removed by exposing the sacrificial insulative structures 206′, 206, 206″ to an etch chemistry, such as a wet etch chemistry. The etch chemistry may include at least one wet etchant comprising one or more of phosphoric acid, sulfuric acid, hydrochloric acid, nitric acid, or another suitable etch chemistry. The sacrificial insulative structures 206′, 206, 206″ may, for example, be removed by exposing the sacrificial insulative structures 206′, 206, 206″ to a so-called “wet nitride strip” comprising phosphoric acid. In some embodiments, the sacrificial insulative structures 206′ of the first stack structures 201′, the sacrificial insulative structures 206 of the second stack structures 201, and the sacrificial insulative structures 206″ of the third stack structures 205 may be removed simultaneously through the replacement gate slots 240.

In addition, as shown in FIG. 8, the sacrificial dielectric material 271 of the sacrificial isolation structure 272 may be at least partially (e.g., substantially) removed through the replacement gate slots 240 during the removal of the sacrificial insulative structures 206′, 206, 206″ to provide a void structure 273. In some embodiments, the sacrificial dielectric material 271 of the sacrificial isolation structure 272, the sacrificial insulative structures 206′ of the first stack structures 201′, the sacrificial insulative structures 206 of the second stack structures 201, and/or the sacrificial insulative structures 206″ of the third stack structures 205 may be removed simultaneously through the replacement gate slots 240. The void structure 273 includes openings extending vertically through the third stack structures 205, and openings extending horizontally in the third stack structures 205. The vertically extending openings intersect with the horizontally extending openings in the third stack structures 205.

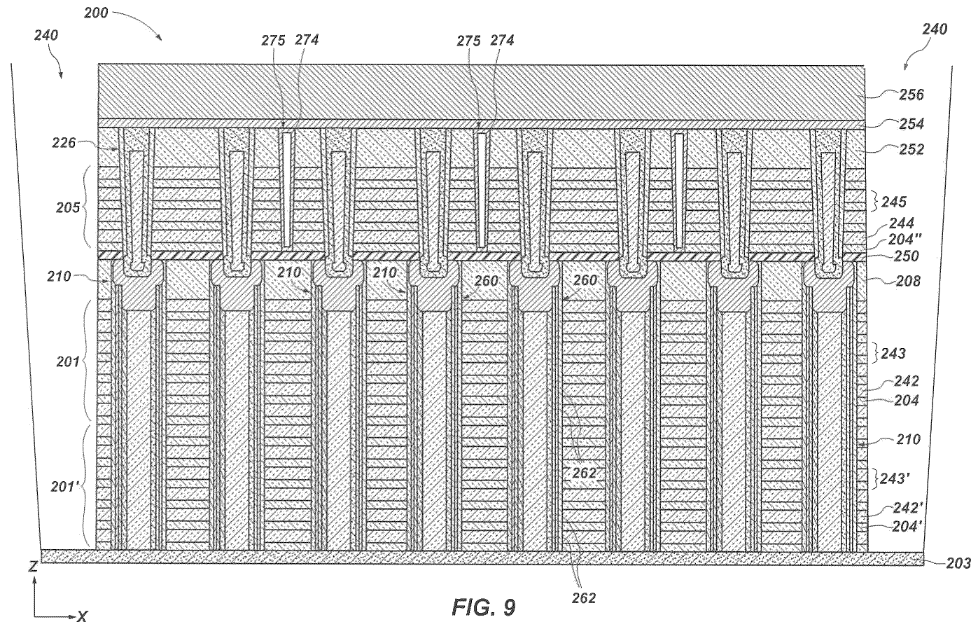

Referring to FIG. 9, conductive structures 242′, 242 may be formed between the vertically neighboring insulative structures 204′, 204 at locations corresponding to the previous locations of the sacrificial insulative structures 206′, 206 of the first and stack structures 201′, 201, to provide tiers 243′, 243 of the first and second stack structures 201′, 201, respectively. Conductive structures 244 may be formed between the vertically neighboring insulative structures 204″ at locations corresponding to the previous locations of the sacrificial insulative structures 206″ of the third stack structure 205, to form tiers 245 of the third stack structure 205. Each of the conductive structures 242′, 242 and 244 may be formed of and include any conductive material including, but not limited to, n-doped polysilicon, p-doped polysilicon, undoped polysilicon, or a metal. In other embodiments, at least one of the conductive structures 242′, 242 and 244 comprise tungsten. In some embodiments, at least one of the conductive structures 242′, 242 and 244 comprise n-doped polysilicon. The conductive structures 244 of the third stack structure 205 may comprise the same material composition as the conductive structures 242′, 242 of the first and second stack structures 201′, 201.

As shown in FIG. 9, the first stack structure 201′ may comprise the vertically alternating arrangement of conductive structures 242′ and the insulative structures 204′ arranged in tiers 243′. The second stack structure 201 may comprise the vertically alternating arrangement of conductive structures 242 and the insulative structures 204 arranged in tiers 243. Formation of the conductive structures 242′, 242 may define strings 260 of memory cells 262. The memory cells 262 of the strings 260 may be located at intersections of the first pillar structure 210′ and the conductive structures 242′, and at intersections of the second pillar structure 210 and the conductive structures 242. The memory cells 262 of the strings 260 may individually include a portion of one of the first pillar structure 210′ and a portion of one of the conductive structures 242′, and a portion of one of the second pillar structure 210 and a portion of one of the conductive structures 242. Vertically neighboring memory cells 262 of the strings 260 may be separated from each other by one of the insulative structures 204′, 204. The third stack structure 205 may comprise the vertically alternating arrangement of conductive structures 244 and the insulative structures 204″ arranged in tiers 245. The conductive structures 244 of the third stack structure 205 may function as select gate structures such as select gate drain structures, or access lines such as word lines.

In some embodiments, the conductive structures 242′, 242 of the first and second stack structures 201′, 201 may include a conductive liner material (not shown) around the conductive structures 242′, 242, such as between the conductive structures 242′, 242 and the insulative structures 204′, 204. In addition, the conductive structures 244 of the third stack structures 205 may include a conductive liner material (not shown) around the conductive structures 244, such as between the around the conductive structures 244 and the insulative structures 204″. The conductive liner material may comprise, for example, a seed material from which the conductive structures 242′, 242, and 244 may be formed. The conductive liner material may be formed of and include, for example, a metal (e.g., titanium, tantalum), a metal nitride (e.g., tungsten nitride, titanium nitride, tantalum nitride), or another material. In some embodiments, the conductive liner material comprises titanium nitride.

With continued reference to FIG. 9, the void structure 273 (FIG. 8) may be at least partially filled with a sacrificial conductive material 274 to provide a sacrificial structure 275. The sacrificial conductive material 274 may be formed of and include any conductive material that exhibits etch selectivity relative to surrounding materials (e.g., the conductive structures 244). In some embodiments, as shown in FIG. 9, the sacrificial structure 275 is not completely filled with the sacrificial conductive material 274, but rather, the sacrificial structure 275 includes a void therein. The void may be formed by non-conformally (e.g., sub-conformally) forming the sacrificial conductive material 274 in the void structure 273. The sub-conformally formed sacrificial conductive material 274 may include one or more interfaces (e.g., one or more seams), which introduces one or more defects into the sacrificial structure 275. The seam may be caused by a difference in size between a height of the conductive structures 244 and a width (e.g., horizontal dimension) of the sacrificial structure 275. In other words, the width of the sacrificial structure 275 is larger than the height of the conductive structures 244.

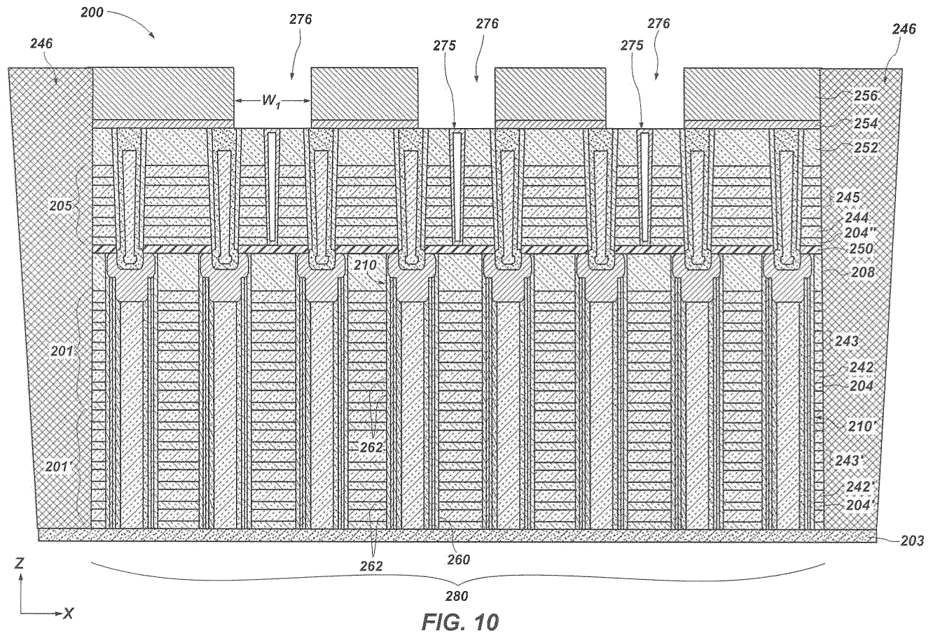

Referring to FIG. 10, the replacement gate slots 240 may be filled (e.g., substantially filled) with a conductive material to form inter-block pillar structures 246 extending vertically through the first stack structure 201′, the second stack structure 201, and the third stack structure 205. Accordingly, the inter-block pillar structures 246 may physically separate the electronic device 200 into blocks 280. A lateral dimension (e.g., a width, a diameter in a horizontal direction) of one or more of the inter-block pillar structures 246 may be relatively larger than a lateral dimension of one or more (e.g., each) of the first pillar structure 210′, the second pillar structure 210, and the third pillar structure 226. While two of the inter-block pillar structures 246 are shown in FIG. 10 for convenience, the disclosure is not so limited, and the electronic device 200 may include a different number of the inter-block pillar structures 246. The inter-block pillar structures 246 may be formed of and includes one or more of an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride); an oxynitride material (e.g., silicon oxynitride); a dielectric carbon nitride material (e.g., silicon carbon nitride); a dielectric carboxynitride material (e.g., silicon carboxynitride); polycarbon; spin-on carbon; or combinations thereof.

As seen in FIG. 10, openings 276 may be formed extending vertically through the uppermost insulative material 256 and the barrier material 254. The openings 276 may expose portions of the upper insulative material 252 and the upper surface of the sacrificial structure 275. A width W₁ of the openings 276 may be greater than a width of the sacrificial structure 275. The openings 276 may be formed (e.g., patterned) using substantially linear (e.g., substantially straight) openings in a resist material (e.g., a photoresist material, a mask material) (not shown) in the Y-direction. For example, the electronic device 200 may be exposed to one or more etchants through a mask (not shown) to remove portions of the uppermost insulative material 256 and the barrier material 254.

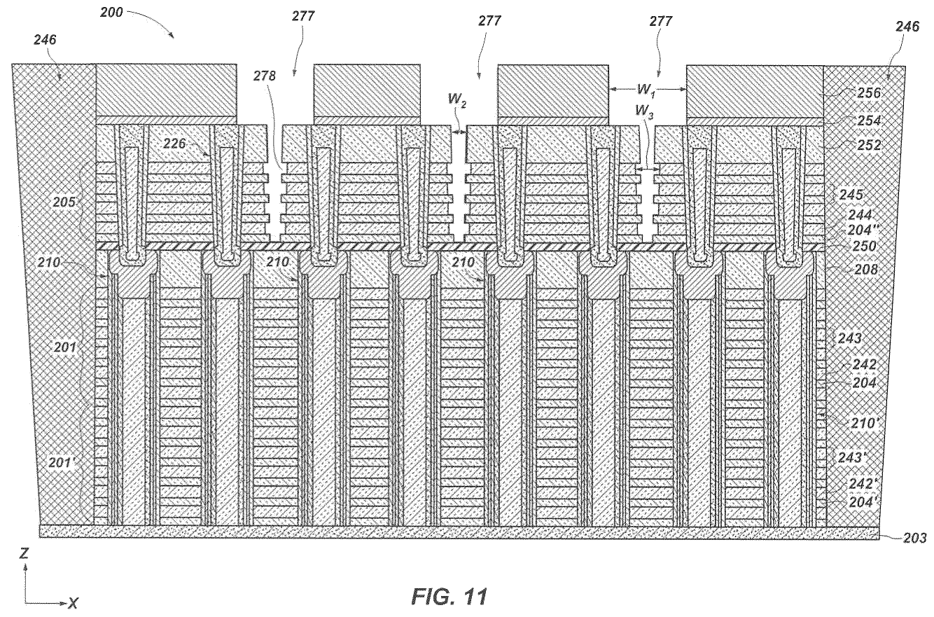

Referring to FIG. 11, following formation of the openings 276, the electronic device 200 of FIG. 10, may be subjected to a single etch process or multiple etch process to create enlarged openings 277 by removing at least a portion of the sacrificial structure 275 underlying the openings 276 (FIG. 10). By way of example only, the sacrificial structure 275 may be substantially removed relative to the upper insulative material 252, and the conductive structures 244 and the insulative structures 204″ in the tiers 245 of the third stack structure 205. The enlarged openings 277 may extend vertically into the tiers 245 of the third stack structure 205 and horizontally into the conductive structures 244 of the tiers 245. A depth of the enlarged openings 277 is, therefore, increased by extending the openings 276 into the third stack structure 205 and by increasing a width laterally adjacent to the conductive structures 244. The width W₁ of the enlarged openings 277 laterally adjacent to the uppermost insulative material 256 and the barrier material 254 may be greater than a width W₂ of the enlarged openings 277 laterally adjacent to the upper insulative material 252 and a width W₃ of the enlarged openings 277 laterally adjacent to the tiers 245. The width W₃ of the enlarged openings 277 laterally adjacent to the tiers 245 may be greater than the width W₂ of the enlarged openings 277 laterally adjacent to the upper insulative material 252.

A portion of the conductive structures 244 of the third stack structure 205 may be selectively removed relative to the vertically adjacent insulative structure 204, to recess sidewalls of the conductive structures 244 relative to sidewalls of the vertically adjacent insulative structure 204″. The vertical dimension (e.g., height) of the recesses may be substantially the same as the vertical dimension (e.g., height) of the adjacent conductive structure 244. The recesses may be formed by laterally removing portions of the conductive structures 244. In some embodiments, the recesses may be formed by wet etching the electronic device 200 after extending the depth of the enlarged openings 277 into the third stack structure 205. In some embodiments, the recesses may be formed using the same etch process that increases the depth of the enlarged openings 277 into the third stack structure 205. For example, the electronic device 200 of FIG. 10 may be subjected to a single etch process that selectively etches the sacrificial structure 275 underlying the openings 276 relative to the upper insulative material 252, and the conductive structures 244 and the insulative structures 204″ of the third stack structure 205, and selectively etches the conductive structures 244 relative to the vertically adjacent insulative structures 204″ and the upper insulative material 252, thus creating the enlarged openings 277 having the recesses vertically adjacent to the conductive structure 244. In some embodiments, the depth of the enlarged openings 277 is increased first, and then the recesses are subsequently formed.

Although FIG. 11 shows that the enlarged openings 277 have the recesses, the disclosure is not limited. In other embodiments, the enlarged openings 277 may not include any recesses or the recesses are only present adjacent to some of the conductive structures 244. The enlarged openings 277 may include a relatively wider upper portion and a relatively narrower lower portion that vertically extends into the third stack structure 205. The lower portion of the enlarged openings 277 may optionally include the recesses.

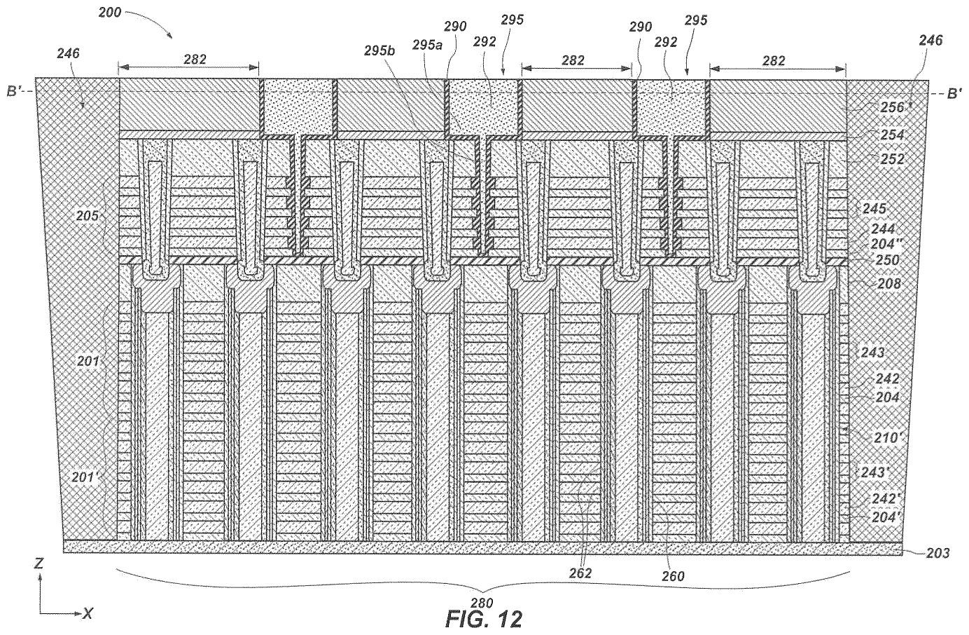

Referring to FIG. 12, an optional dielectric liner 290 may be formed substantially conformally on the sidewalls of the material defining the enlarged openings 277 (whether including the recess structures 278 or not). In other words, the dielectric liner 290 (if present) may be formed substantially conformally on the exposed surfaces of the uppermost insulative material 256 and the barrier material 254, the exposed surface of the upper insulative material 252, and the exposed surfaces of the vertically alternating conductive structures 244 and the insulative structures 204″ of the third stack structure 205. In some embodiments, the dielectric liner 290 is formed of and includes a nitride material. In some embodiments, the dielectric liner 290 is formed of and includes silicon nitride. In some embodiments, the dielectric liner 290 is formed of and includes silicon oxycarbonitride. In other embodiments, the dielectric liner 290 is formed of and includes silicon oxynitride. Furthermore, in some embodiments wherein the enlarged openings 277 includes the recesses, the dielectric liner 290 may fill (e.g., substantially completely fill) the recesses, as shown in FIG. 12. Therefore, the dielectric liner 290 may be located in the recesses laterally adjacent to the conductive structures 244. Portions of the dielectric liner 290 may, therefore, extend to the recessed sidewalls of the conductive structures 244.

The enlarged openings 277 may then be filled (e.g., substantially filled) with a dielectric material 292 to create isolated dielectric structures 295. The dielectric material 292 may be formed of and include, for example, an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride), an oxynitride material (e.g., silicon oxynitride), a dielectric carbon nitride material (e.g., silicon carbon nitride), a dielectric carboxynitride material (e.g., silicon carboxynitride), or combinations thereof. The dielectric material 292 may have substantially the same material composition as the insulative structures 204′ of the first stack structure, the insulative structures 204 of the second stack structure 201, and/or the insulative structures 204″ of the third stack structure 205. In some embodiments, the dielectric material 292 comprises silicon oxide. If no dielectric liner 290 is present, the dielectric material 292 may be formed in the recesses laterally adjacent to the conductive structures 244. Portions of the dielectric material 292 may, therefore, extend to the recessed sidewalls of the conductive structures 244.

As shown in FIG. 12, the isolated dielectric structures 295 may segment the blocks 180 of the electronic device 200 into sub-blocks 282, each defined within horizontal boundaries between the neighboring isolated dielectric structures 295. While three of the isolated dielectric structures 295 are shown in FIG. 12 for convenience, the disclosure is not so limited, and the electronic device 200 may include a different number of the isolated dielectric structures 295.

Accordingly, the isolated dielectric structures 295 may segment the conductive structures 244 of the tiers 245 of the third stack structure 205 into discrete portions within the different sub-blocks 282 such that the conductive structures 244 do not extend substantially continuously within the blocks 280 and the sub-blocks 282. Rather, such conductive structures 244 may be segmented by the isolated dielectric structures 295. In other words, the isolated dielectric structures 295 may electrically isolate the conductive structures 244 of the third stack structure 205 into sub-blocks 282 within the blocks 180 of the electronic device 200.

Due to the different widths (e.g., W₁, W₂, W₃) of the enlarged openings 277, the isolated dielectric structures 295 may be composed of two portions 295a and 295b. The first portion (e.g., the upper portion) 295a may be positioned between the laterally adjacent uppermost insulative materials 256, while the second portion (lower portion) 295b may extend vertically through the upper insulative material 252 and the tiers 245 of the vertically alternating conductive structures 244 and the insulative structure 204″ of the third stack structure 205, A width of the upper portion 295a of the isolated dielectric structures 295 may be greater than a width of the lower portion, 295b. In some embodiments, the lower portion 295b of the isolated dielectric structure 295 may be located between the neighboring third pillar structures (channel pillars) 226. In some embodiments, the lower portion 295b of the isolated dielectric structure 295 may be substantially centered between neighboring third pillar structures 226.

By forming the sacrificial isolation structure 272 (see FIG. 5) (which becomes the isolated dielectric structure 295 in the subsequent processing acts as discussed above) prior to conducting the gate replacement process, the bending of blocks 180 in the subsequent processing acts may be minimized or prevented. Therefore, the isolated dielectric structure 295 and the third pillar structures 226 of the electronic device 200 may be less prone to mis-alignment compared to the conventional electronic device such as the electronic device 100 formed by the conventional method shown in FIGS. 1 and 2.

Furthermore, the openings 270 in FIG. 4 (which lead to the formation of the isolated dielectric structure 295 in the subsequent processing acts as discussed above) according to embodiments of the disclosed method may be formed by etching portions of the vertically alternating insulative structures 204″ and the sacrificial insulative structures 206″ of the tiers 224″ (e.g., etching oxide materials and nitride materials of the tiers 224″). In contrast, the openings (which lead to the formation of the isolated dielectric structures 176, 176′ of FIG. 2 in the subsequent processing acts) according to the conventional method are formed by etching the vertically alternating insulative structures 104 and the conductive structures 144 (e.g., etching oxide materials and metal materials). Since etching the oxide and nitride materials is more controllable than etching the oxide and metal materials, embodiments of the disclosed method provide more control over critical dimensions of features than the conventional method. Therefore, the openings 270 in FIG. 4 according to embodiments of the disclosed method may be formed with a smaller critical dimension than the openings that lead to the formation of the isolated dielectric structures 176, 176′ in FIG. 2 according to the conventional method. The different relative widths in the enlarged openings 277 may enable the upper portion 295a and the lower portion 295b of the isolated dielectric structure 295 to be different widths, with the upper portion 295a being relatively wider than the lower portion 295b. The greater width of the upper portion of the enlarged openings 277 may enable the recesses to be selectively formed adjacent to the conductive structures 244.

Accordingly, the embodiments of the disclosed method allow for smaller critical dimensions to be formed in the horizontal direction of the isolated dielectric structure that divides the electronic device into sub-blocks (e.g., a smaller footprint in the horizontal direction), increasing the memory density of the disclosed electronic device compared to the conventional electronic device. Moreover, the embodiments of the disclosed method may be less expensive. It is expensive to etch through oxide and metal materials of the tiers of the third stack structure as required in the conventional method of forming an electronic device. The embodiments of the disclosed method do not require etching through oxide and metal materials. Rather, the embodiments of the disclosed method involve etching through oxide and nitride materials, which is less costly to perform compared to etching through oxide and metal materials.

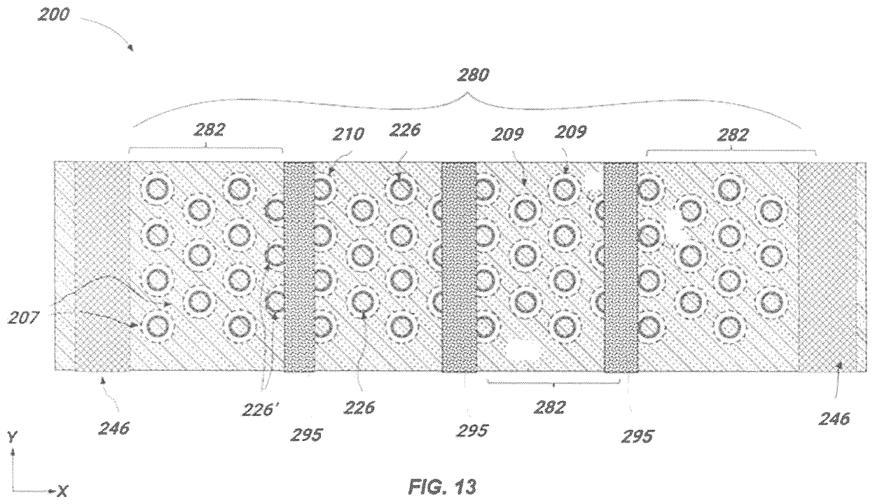

FIG. 13 is a partial top-down view along line B-B′ of the microelectronic device view of the electronic device 200 of FIG. 12. For convenience and ease of understanding the drawings and associated description, surrounding materials including the uppermost insulative material 256 and the barrier material 254 are absent in FIG. 13.

The electronic device 200 may be segmented into blocks 280 between the horizontally neighboring inter-block pillar structures 246 (e.g., in the X-direction). Each block 280 may be segmented into sub-blocks 282 between horizontally neighboring isolated dielectric structures 295 (e.g., in the X-direction). Each sub-block 282 includes the first pillar structures 210′, the second pillar structures 210, and the third pillar structures 226 arranged in rows 207 and columns 209. A lateral dimension (e.g., a width, a diameter in the X-direction) of one or more of the inter-block pillar structures 246 may be relatively larger than a lateral dimension of one or more (e.g., each) of the first pillar structures 210′, the second pillar structures 210, and the third pillar structures 226. While two of the inter-block pillar structures 246 are shown in FIG. 13 for convenience, the disclosure is not so limited, and the electronic device 200 may include a different number of the inter-block pillar structures 246. Furthermore, while three of the isolated dielectric structures 295 are shown in FIG. 13 for convenience, the disclosure is not so limited, and the electronic device 200 may include a different number of the isolated dielectric structures 295.

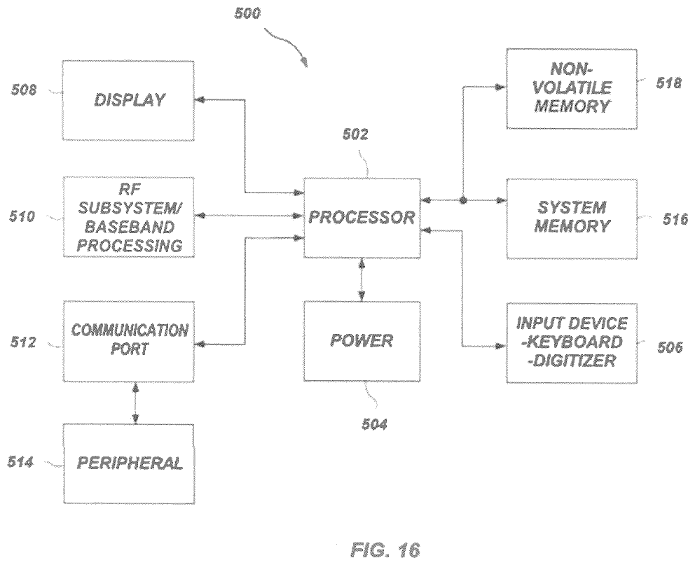

As shown in FIG. 13, some of the second pillar structures 210 may be aligned with each other (e.g., in the Y-direction), and some of the second pillar structures 210 may be offset from each other (e.g., in the Y-direction). The second pillar structures 210 may be arranged in a hexagonal close-packed arrangement, which may facilitate an increased density of the second pillar structures 210 (and the resulting strings 260 of memory cells 262) in the second stack structure 201. The second pillar structures 210 may be arranged in rows 207 extending in a first horizontal (e.g., lateral) direction (e.g., in the X-direction) and columns 209 extending in a second horizontal direction (e.g., in the Y-direction). In FIG. 13, the second pillar structures 210 are illustrated in broken lines to indicate that they are located below an upper surface of the electronic device 200, and the first pillar structures 210′ (not shown in FIG. 16) are beneath the second pillar structures 210.

Likewise, the third pillar structure 226 may be similarly arranged in the rows 207 extending in the first horizontal (e.g., lateral) direction (e.g., in the X-direction) and in the columns 209 extending in the second horizontal direction (e.g., in the Y-direction). Each of the third pillar structures 226 may be substantially horizontally aligned with the second pillar structure 210 (e.g., in each of the X-direction and the Y-direction). In other words, a center of the third pillar structures 226 may be substantially horizontally aligned with a center of an underlying second pillar structure 210.

While FIG. 13 shows some of the third pillar structures 226 as being horizontally aligned with the second pillar structures 210, at least some of the third pillar structures 226′ may be horizontally offset from the center of the underlying second pillar structure 210. Although FIG. 16 illustrates three of the additional second pillar structure 226′ in a single column 209, the disclosure is not so limited. For example, the electronic device 200 may include additional columns 209 of the additional second pillar structure 226′.

As shown in FIG. 13, each of the second pillar structures 210 and the third pillar structures 226 may individually exhibit a substantially circular cross-sectional shape. However, the disclosure is not so limited, and additional configurations may be contemplated. For example, one or more of the second pillar structures 210 and the third pillar structure 226 may individually exhibit a substantially rectangular cross-sectional shape (e.g., a substantially square cross-sectional shape).

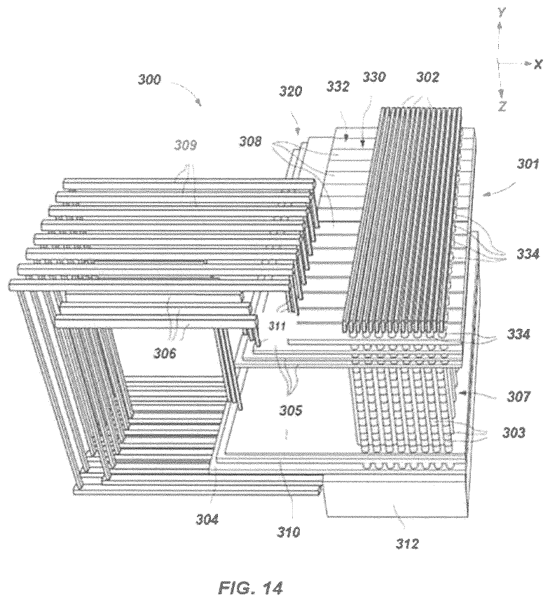

FIG. 14 illustrates a partial cutaway perspective view of a portion of an electronic device 300 (e.g., a microelectronic device, a memory device, such as a 3D NAND Flash memory device) including one or more electronic device structures 301 (e.g., a microelectronic device structure). The electronic device 300 may include structures substantially similar to the electronic device 200 previously described with reference to FIG. 12. As shown in FIG. 14, the electronic device structure 301 of the electronic device 300 may include a staircase structure 320 defining contact regions for connecting interconnect lines 306 to conductive structures 305 (e.g., corresponding to the conductive structures 242′, 242, 244 (FIG. 12)). The electronic device structure 301 may include vertical strings 307 (e.g., corresponding to the strings 260 (FIG. 12)) of memory cells 303 (e.g., corresponding to the memory cells 262 (FIG. 12)) that are coupled to each other in series. The vertical strings 307 may extend vertically (e.g., in the Z-direction) and orthogonally to conductive lines and the conductive structures 305, such as data lines 302, a source tier 304 (e.g., corresponding to the source 203 (FIG. 12)), the conductive structures 305, the interconnect lines 306, first select gates 308 (e.g., upper select gates, drain select gates (SGDs)), such as the tiers 245 of the third stack structure 205 (FIG. 12), select lines 309, and a second select gate 310 (e.g., a lower select gate, a source select gate (SGS)). The first select gates 308 may be horizontally divided (e.g., in the Y-direction) into multiple blocks 332 (e.g., corresponding to the blocks 280 (FIG. 12)) horizontally separated (e.g., in the Y-direction) from one another by slots 330 (e.g., corresponding to the conductive structures 246 (FIG. 12)).

Vertical conductive contacts 311 may electrically couple components to each other as shown. For example, the select lines 309 may be electrically coupled to the first select gates 308 and the interconnect lines 306 may be electrically coupled to the conductive structures 305. The electronic device 300 may also include a control unit 312 positioned under the memory array, which may include at least one of string driver circuitry, pass gates, circuitry for selecting gates, circuitry for selecting conductive lines (e.g., the data lines 302, the interconnect lines 306), circuitry for amplifying signals, and circuitry for sensing signals. The control unit 312 may be electrically coupled to the data lines 302, the source tier 304, the interconnect lines 306, the first select gates 308, and the second select gates 310, for example. In some embodiments, the control unit 312 includes CMOS (complementary metal-oxide-semiconductor) circuitry. In such embodiments, the control unit 312 may be characterized as having a “CMOS under Array” (“CuA”) configuration.

The first select gates 308 may extend horizontally in a first direction (e.g., the X-direction) and may be coupled to respective first groups of vertical strings 307 of memory cells 303 at a first end (e.g., an upper end) of the vertical strings 307. The second select gate 310 may be formed in a substantially planar configuration and may be coupled to the vertical strings 307 at a second, opposite end (e.g., a lower end) of the vertical strings 307 of memory cells 303.

The data lines 302 (e.g., digit lines, bit lines) may extend horizontally in a second direction (e.g., in the Y-direction) that is at an angle (e.g., perpendicular) to the first direction in which the first select gates 308 extend. Individual data lines 302 may be coupled to individual groups of the vertical strings 307 extending the second direction (e.g., the Y-direction) at the first end (e.g., the upper end) of the vertical strings 307 of the individual groups. Additional individual groups of the vertical strings 307 extending the first direction (e.g., the X-direction) and coupled to individual first select gates 308 may share a particular vertical string 307 thereof with individual group of vertical strings 307 coupled to an individual data line 302. Thus, an individual vertical string 307 of memory cells 303 may be selected at an intersection of an individual first select gate 308 and an individual data line 302. Accordingly, the first select gates 308 may be used for selecting memory cells 303 of the vertical strings 307 of memory cells 303.

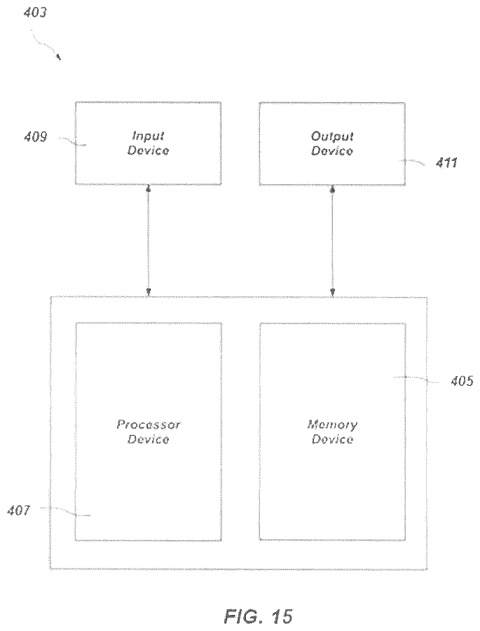

The conductive structures 305 (e.g., word lines, such as the conductive structures 242 (FIG. 15)) may extend in respective horizontal planes. The conductive structures 305 may be stacked vertically, such that each conductive structure 305 is coupled to at least some of the vertical strings 307 of memory cells 303, and the vertical strings 307 of the memory cells 303 extend vertically through the stack structure including the conductive structures 305. The conductive structures 305 may be coupled to or may form control gates of the memory cells 303.

The first select gates 308 and the second select gates 310 may operate to select a vertical string 307 of the memory cells 303 interposed between data lines 302 and the source tier 304. Thus, an individual memory cell 303 may be selected and electrically coupled to a data line 302 by operation of (e.g., by selecting) the appropriate first select gate 308, second select gate 310, and conductive structure 305 that are coupled to the particular memory cell 303.

The staircase structure 320 may be configured to provide electrical connection between the interconnect lines 306 and the conductive structures 305 through the vertical conductive contacts 311. In other words, an individual conductive structure 305 may be selected via an interconnect line 306 in electrical communication with a respective vertical conductive contact 311 in electrical communication with the conductive structure 305. The data lines 302 may be electrically coupled to the vertical strings 307 through conductive contacts 334.

Thus, in accordance with embodiments of the disclosure, an electronic device comprises a first stack structure, a second stack structure overlying the first stack structure, a third stack structure overlying the second stack structure, a first pillar structure extending vertically through the first stack structure, a second pillar structure extending vertically through the second stack structure, a third pillar structure extending vertically through the third stack structure. Each of the first, second and third stack structures comprises tiers of vertically alternating conductive structures and insulative structures. Each of the first and second pillar structures comprising strings of memory cells and a channel structure. The third pillar structure comprises a channel material. The electronic device comprises also comprises an inter-block pillar structure and an isolated dielectric structure. The inter-block pillar structure extends vertically through the first, second and third stack structures, and segments the first, second and third stack structures into blocks. The isolated dielectric structure segments the blocks into sub-blocks. The isolated dielectric structure comprises an upper portion and a lower portion. The upper portion of the isolated dielectric structure exhibits a relatively larger width than the lower portion of the isolated dielectric structure.

Thus, in accordance with additional embodiments of the disclosure, an electronic device comprises a stacked structure divided into blocks, a memory pillar comprising strings of memory cells, a channel pillar comprising a channel material, an inter-block pillar structure interposed horizontally between the blocks of the stacked structure, and an isolated dielectric structure segmenting the blocks into sub-blocks. The stacked structure comprises a first stack structure overlying a source, a second stack structure overlying the first stack structure, and a third stack structure overlying the second stack structure. Each of the first, second and third stack structures comprises tiers of vertically alternating conductive structures and insulative structures. The memory pillar extends vertically through the first and second stack structures. The channel pillar extends vertically through the third stack structure. The isolated dielectric structure comprises a first portion and a second portion over the first portion. The first portion overlies the third stack structure. The second portion extends vertically through at least a portion of the third stack structure.

Thus, in accordance with additional embodiments of the disclosure, a method of forming an electronic device comprises forming a first stack structure overlying a source and a first pillar structure extending vertically through the first stack structure, forming a second stack structure overlying the first stack structure and a second pillar structure extending vertically through the second stack structure, and forming a third stack structure overlying the second stack structure. Each of the first, second and third stack structures comprises sacrificial insulative structures and insulative structures vertically alternating with the sacrificial insulative structures. The method further comprises forming a sacrificial isolation structure extending vertically through at least a portion of the third stack structure, forming a third pillar structure extending vertically through the third stack structure, and forming an uppermost insulative material over the third stack structure. The sacrificial isolation structure comprises a sacrificial dielectric material. After forming the sacrificial isolation structure, a replacement gate slot is formed extending vertically through the first, second and third stack structures, and the uppermost insulative material. The sacrificial dielectric material of the sacrificial isolation structure is removed to form a void structure. Then, the void structure is at least partially filled with a sacrificial conductive material to provide a sacrificial structure. The method also comprises replacing the sacrificial insulative structures in the first, second and third stack structures with conductive structures, resulting in each of the first, second and third stack structures comprises the conductive structures and the insulative structures vertically alternating with the conductive structures. Upon substantially filling the replacement gate slot with a conductive material, an inter-block pillar structure is formed segmenting the first, second, and third stack structures into blocks. An opening is formed extending vertically through the uppermost insulative material and exposing the upper surface of the sacrificial structure. The method comprises forming an enlarged opening by removing at least a portion of the sacrificial structure underlying the openings. Upon substantially filling the enlarged openings with a dielectric material, an isolated dielectric structure is formed segmenting the blocks into sub-blocks. The isolated dielectric structure comprises an upper portion exhibiting a relatively larger width than a lower portion. The lower portion of the isolated dielectric structure extends vertically through at least a portion of the third stack structure.

Electronic devices (e.g., the electronic device 200) according to some embodiments of the disclosure, comprising the inter-block pillar structure 246 segmenting the stacked structure 201′, 201, 205 of the device into blocks 280, and the isolated dielectric structure 295 segmenting the blocks 280 into sub-blocks 282, wherein the isolated dielectric structure 295 is composed of a first portion 295a interposed horizontally between two adjacent insulative materials 256 overlying the third stack structure 205, and a second portion 295b extending vertically through at least a portion of the third stack structure 205, may be used in embodiments of electronic systems of the disclosure. For example, FIG. 15 is a block diagram of an electronic system 403, in accordance with embodiments of the disclosure. The electronic system 403 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 403 includes at least one memory device 405. The memory device 405 may include, for example, an embodiment of an electronic device (e.g., the electronic device 200 previously described with reference to FIG. 12) including the inter-block pillar structure 246 segmenting the stacked structure 201′, 201, 205 of the device into blocks 280, and the isolated dielectric structure 295 segmenting the blocks 280 into sub-blocks 282, wherein the isolated dielectric structure 295 is composed of a first portion 295a interposed horizontally between two adjacent insulative materials 256 overlying the third stack structure 205, and a second portion 295b extending vertically through at least a portion of the third stack structure 205.

The electronic system 403 may further include at least one electronic signal processor device 407 (often referred to as a “microprocessor”). The electronic signal processor device 407 may optionally include an embodiment of an electronic device (e.g., the electronic device 200 previously described with reference to FIG. 12). The electronic system 403 may further include one or more input devices 409 for inputting information into the electronic system 403 by a user, such as, for example, a mouse or other pointing device, a keyboard, a touchpad, a button, or a control panel. The electronic system 403 may further include one or more output devices 411 for outputting information (e.g., visual or audio output) to a user such as, for example, a monitor, a display, a printer, an audio output jack, a speaker, etc. In some embodiments, the input device 409 and the output device 411 may comprise a single touchscreen device that can be used both to input information to the electronic system 403 and to output visual information to a user. The input device 409 and the output device 411 may communicate electrically with one or more of the memory device 405 and the electronic signal processor device 407.

With reference to FIG. 16, depicted is a processor-based system 500. The processor-based system 500 may include various electronic devices (e.g., the electronic device 200 manufactured in accordance with embodiments of the present disclosure). The processor-based system 500 may be any of a variety of types such as a computer, pager, cellular phone, personal organizer, control circuit, or other electronic device. The processor-based system 500 may include one or more processors 502, such as a microprocessor, to control the processing of system functions and requests in the processor-based system 500. The processor 502 and other subcomponents of the processor-based system 500 may include electronic devices (e.g., the electronic device 200 manufactured in accordance with embodiments of the present disclosure).

The processor-based system 500 may include a power supply 504 in operable communication with the processor 502. For example, if the processor-based system 500 is a portable system, the power supply 504 may include one or more of a fuel cell, a power scavenging device, permanent batteries, replaceable batteries, and rechargeable batteries. The power supply 504 may also include an AC adapter; therefore, the processor-based system 500 may be plugged into a wall outlet, for example. The power supply 504 may also include a DC adapter such that the processor-based system 500 may be plugged into a vehicle cigarette lighter or a vehicle power port, for example.

Various other devices may be coupled to the processor 502 depending on the functions that the processor-based system 500 performs. For example, a user interface 506 may be coupled to the processor 502. The user interface 506 may include input devices such as buttons, switches, a keyboard, a light pen, a mouse, a digitizer and stylus, a touch screen, a voice recognition system, a microphone, or a combination thereof. A display 508 may also be coupled to the processor 502. The display 508 may include an LCD display, an SED display, a CRT display, a DLP display, a plasma display, an OLED display, an LED display, a three-dimensional projection, an audio display, or a combination thereof. Furthermore, an RF sub-system/baseband processor 510 may also be coupled to the processor 502. The RF sub-system/baseband processor 510 may include an antenna that is coupled to an RF receiver and to an RF transmitter (not shown). A communication port 512, or more than one communication port 512, may also be coupled to the processor 502. The communication port 512 may be adapted to be coupled to one or more peripheral devices 514, such as a modem, a printer, a computer, a scanner, or a camera, or to a network, such as a local area network, remote area network, intranet, or the Internet, for example.

The processor 502 may control the processor-based system 500 by implementing software programs stored in the memory. The software programs may include an operating system, database software, drafting software, word processing software, media editing software, or media playing software, for example. The memory is operably coupled to the processor 502 to store and facilitate execution of various programs. For example, the processor 502 may be coupled to system memory 516, which may include one or more of spin torque transfer magnetic random access memory (STT-MRAM), magnetic random access memory (MRAM), dynamic random access memory (DRAM), static random access memory (SRAM), racetrack memory, and other known memory types. The system memory 516 may include volatile memory, non-volatile memory, or a combination thereof. The system memory 516 is typically large so that it can store dynamically loaded applications and data. In some embodiments, the system memory 516 may include semiconductor devices, such as the electronic devices (e.g., the electronic device 200) described above, or a combination thereof.

The processor 502 may also be coupled to non-volatile memory 518, which is not to suggest that system memory 516 is necessarily volatile. The non-volatile memory 518 may include one or more of STT-MRAM, MRAM, read-only memory (ROM) such as an EPROM, resistive read-only memory (RROM), and flash memory to be used in conjunction with the system memory 516. The size of the non-volatile memory 518 is typically selected to be just large enough to store any necessary operating system, application programs, and fixed data. Additionally, the non-volatile memory 518 may include a high-capacity memory such as disk drive memory, such as a hybrid-drive including resistive memory or other types of non-volatile solid-state memory, for example. The non-volatile memory 518 may include electronic devices, such as the electronic devices (e.g., the electronic device 200 described above), or a combination thereof.

Thus, in accordance with embodiments of the disclosure a system comprises a processor operably coupled to an input device and an output device, and the disclosed electronic device operably coupled to the processor.

The electronic devices and systems of the disclosure advantageously facilitate one or more of improved simplicity, greater packaging density, and increased miniaturization of components as compared to conventional devices and conventional systems. The methods of the disclosure facilitate the formation of devices (e.g., apparatuses, microelectronic devices, memory devices) and systems (e.g., electronic systems) having one or more of improved performance, reliability, and durability, lower costs, increased yield, increased miniaturization of components, improved pattern quality, and greater packaging density as compared to conventional devices (e.g., conventional apparatuses, conventional electronic devices, conventional memory devices) and conventional systems (e.g., conventional electronic systems).

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
a first stack structure;
a second stack structure overlying the first stack structure;
a third stack structure overlying the second stack structure, each of the first, second and third stack structures comprising tiers of vertically alternating conductive structures and insulative structures;
a first pillar structure extending vertically through the first stack structure;
a second pillar structure extending vertically through the second stack structure, each of the first and second pillar structures comprising strings of memory cells and a channel structure;
a third pillar structure extending vertically through the third stack structure and comprising a channel material;
an inter-block pillar structure extending vertically through the first, second and third stack structures and segmenting the first, second and third stack structures into blocks; and
an isolated dielectric structure segmenting the blocks into sub-blocks, the isolated dielectric structure comprising an upper portion and a lower portion, the upper portion exhibiting a relatively larger width than the lower portion.

2. The electronic device of claim 1, further comprising an uppermost insulative material overlying the third stacked structure, the upper portion of the isolated dielectric structure extending vertically through the uppermost insulative material overlying the third stack structure, the lower portion of the isolated dielectric structure extending vertically through portions of the third stack structure.

3. The electronic device of claim 1, wherein the lower portion of the isolated dielectric structure extends vertically into the tiers of the third stack structure and horizontally into the conductive structures of the tiers of the third stack structure.

4. The electronic device of claim 1, wherein the isolated dielectric structure is interposed laterally between neighboring third pillar structures.

5. The electronic device of claim 1, wherein the first pillar structure substantially horizontally aligns with the second pillar structure, and wherein the second pillar structure substantially horizontally aligns with the third pillar structure.

6. The electronic device of claim 1, wherein the inter-block pillar structure has a larger horizontal dimension than the first, second and third pillar structures.

7. The electronic device of claim 1, further comprising a channel region composed of the channel structure of the first and second stack structures electrically connecting to the channel material of the third stack structure through a conductive contact.

8. The electronic device of claim 1, wherein the conductive structures of the tiers of the third stack structure do not extend substantially continuously within the blocks and the sub-blocks.

9. An electronic device, comprising:
a stacked structure comprising a first stack structure overlying a source, a second stack structure overlying the first stack structure, and a third stack structure overlying the second stack structure, each of the first, second and third stack structures comprising tiers of vertically alternating conductive structures and insulative structures, the stacked structure divided into blocks;
a memory pillar comprising strings of memory cells and extending vertically through the first and second stack structures;
a channel pillar comprising a channel material and extending vertically through the third stack structure;
an inter-block pillar structure interposed horizontally between the blocks of the stacked structure; and
an isolated dielectric structure segmenting the blocks into sub-blocks, the isolated dielectric structure comprising a first portion and a second portion over the first portion, the first portion overlying the third stack structure, the second portion extending vertically through at least a portion of the third stack structure.

10. The electronic device of claim 9, wherein the first portion of the isolated dielectric structure has a larger width than the second portion of the isolated dielectric structure.

11. The electronic device of claim 9, further comprising:
an upper insulating material overlying the third stack structure; and
an uppermost insulating material overlying the upper insulating material,
wherein a width of the isolated dielectric structure laterally adjacent to the uppermost insulative material is greater than a width of the isolated dielectric structure laterally adjacent to the upper insulative material and a width of the isolated dielectric structure laterally adjacent to the conductive structures of the tiers of the third stack structure.

12. The electronic device of claim 11, wherein the width of the isolated dielectric structure laterally adjacent to the conductive structures of the tiers of the third stack structure is greater than the width of the isolated dielectric structure laterally adjacent to the upper insulative material.

13. The electronic device of claim 9, further comprising a dielectric liner interposed between the isolated dielectric structure and the tiers of the third stack structure.

14. The electronic device of claim 13, wherein a width of the dielectric liner laterally adjacent to the conductive structures of the tiers of the third stack structure is greater than a width of the dielectric liner laterally adjacent to the insulative structures of the tiers of the third stack structure.

15. The electronic device of claim 9, wherein the isolated dielectric structure is positioned substantially centered between adjacent channel pillars.

16. A method of forming an electronic device, comprising:
forming a first stack structure overlying a source, a first pillar structure extending vertically through the first stack structure;
forming a second stack structure overlying the first stack structure, a second pillar structure extending vertically through the second stack structure;
forming a third stack structure overlying the second stack structure, each of the first, second and third stack structures comprising sacrificial insulative structures and insulative structures vertically alternating with the sacrificial insulative structures;
forming a sacrificial isolation structure extending vertically through at least a portion of the third stack structure, the sacrificial isolation structure comprising a sacrificial dielectric material;
forming a third pillar structure extending vertically through the third stack structure;
forming an uppermost insulative material over the third stack structure;
after forming the sacrificial isolation structure, forming a replacement gate slot extending vertically through the uppermost insulative material and the first, second and third stack structures;
replacing the sacrificial insulative structures in the first, second and third stack structures with conductive structures, each of the first, second and third stack structures comprising the conductive structures and the insulative structures vertically alternating with the conductive structures;
removing the sacrificial dielectric material of the sacrificial isolation structure to form a void structure and at least partially filling the void structure with a sacrificial conductive material to provide a sacrificial structure;
substantially filling the replacement gate slot with a conductive material to form an inter-block pillar structure segmenting the first, second, and third stack structures into blocks;
forming an opening extending vertically through the uppermost insulative material and exposing an upper surface of the sacrificial structure;
forming an enlarged opening by removing at least a portion of the sacrificial structure underlying the opening; and
substantially filling the enlarged opening with a dielectric material to form an isolated dielectric structure segmenting the blocks into sub-blocks, the isolated dielectric structure comprising an upper portion exhibiting a relatively larger width than a lower portion, the lower portion extending vertically through at least a portion of the third stack structure.

17. The method of claim 16, wherein substantially filling the enlarged openings with the dielectric material to form the isolated dielectric structure comprises:
forming the upper portion of isolated dielectric structure laterally adjacent to the uppermost insulative material; and
forming the lower portion of isolated dielectric structure laterally adjacent to tiers of the third stack structure.

18. The method of claim 16, further comprising removing at least a portion of the conductive structures in the third stack structure to form recesses in the enlarged opening.

19. The method of claim 16, further comprising forming a dielectric liner on sidewalls of the enlarged openings, prior to substantially filling the enlarged openings with the dielectric material to form the isolated dielectric structure.

20. The method of claim 16, wherein forming the sacrificial isolation structure extending vertically through portions of the third stack structure is performed prior to forming the third pillar structure extending vertically through the third stack structure.
